(19) United States
(12) Patent Application Publication
(10) Pub. No.: US 2015/0130490 A1
(43) Pub. Date: May 14, 2015

(54) PROBE APPARATUS FOR TESTING CHIPS

(71) Applicant: Kenzo SUDO, SEOUL (KR)

(72) Inventor: Shigeo Sudo, Tokyo (JP)

(73) Assignee: Kenzo Sudo, Seoul (KR)

(21) Appl. No.: 14/123,928

(22) PCT Filed: Jun. 8, 2012
(86) PCT No.: PCT/KR2012/004545

§ 371 Date: Apr. 30, 2014

(30) Foreign Application Priority Data
Jun. 8, 2011 (JP) 10-2011-0055126

(51) Int. Cl. G01R 31/26; G01R 1/04; G01R 1/18; G01R 1/073

(52) U.S. Cl. CPC G01R 31/2601; G01R 1/073; G01R 1/0416; G01R 1/18
USPC 324/755.01

(57) ABSTRACT

The present invention relates to a probe apparatus for testing the quality of semiconductor chips, wherein the probe apparatus for testing chips has superior reliability and durability. The probe apparatus of the present invention comprises: a printed circuit board having a center with a through-hole; a pin holder which is attached to the front surface of the printed circuit board and which has a plurality of pinholes; a plurality of probe pins, each of which has an L-shape with a horizontal end connected to one side end of a circuit pattern formed on the printed circuit board, and a vertical end exposed outwardly from the upper surface of the pinhole; and a back cover attached to the back surface of the printed circuit board.

### TECHNICAL FIELD

The present invention relates to a probe apparatus for testing semiconductor chips, and more particularly, to a probe apparatus for testing chips with excellent reliability and durability.

### BACKGROUND ART

In general, electronic devices including a plurality of integrated circuit chips are mounted on an electronic product and provide various capabilities to the electronic product. Although such electronic devices were formed of electrically conductive materials, a semiconductor exhibiting an intermediate degree of resistance between a conductor and an insulator has been widely used in recent years.

Integrated circuit chips (hereinafter, referred to as chips) are mounted on such an electronic product to provide various capabilities to the product. Accordingly, before the electronic product is completely assembled by coupling the chips thereto, quality control testing must be performed in order to pass/fail manufactured integrated circuit chips.

### DISCLOSURE

### Technical Problem

The present invention has been made to solve such problems in the art and an aspect of the present invention is to provide a probe apparatus for testing chips with excellent durability and reliability.

Another aspect of the present invention is to provide a probe apparatus for testing chips which can easily identify damage of the probe apparatus.

### Technical Solution

In accordance with one aspect of the present invention, a probe apparatus for testing chips includes: a printed circuit board having a through-hole formed at a center thereof; a pin holder attached to a front surface of the printed circuit board and having a plurality of pinholes formed therethrough; a plurality of probe pins each having an L shape with a vertical end and a horizontal end, the horizontal end of the probe pin being connected to one end of a circuit pattern formed on the printed circuit board, the vertical end of the probe pin being exposed through a top surface of the pinhole; and a rear cover attached to a rear surface of the printed circuit board.

The pin holder and the rear cover may be formed of a transparent material. More specifically, the pin holder may be formed of crystal glass and the pin holder may be formed of a transparent synthetic resin having antistatic properties.

The pin holder and the rear cover may be detachably formed, thereby improving maintenance convenience.

The probe pins may be formed of beryllium copper (BeCu), and each of the probe pins may include a copper plated layer, a nickel plated layer, and a gold plated layer sequentially formed on a surface thereof. In this case, the gold plated layer may have a thickness ranging from 2 μm to 4 μm.

The horizontal end of the probe pins may be bent in the same direction as the vertical end.

The probe apparatus may further include a plurality of support rods coupled to the rear surface of the printed circuit board.

A gap may be formed between the printed circuit board and the rear cover. To this end, a spacer may be disposed between the printed circuit board and the rear cover.

The probe apparatus may further include a female connector connected to the other end of the circuit pattern of the printed circuit board, and in this case, the female connector may be arranged at an edge of the printed circuit board.

### Advantageous Effects

In the probe apparatus according to the present invention, probe pins can be stably connected to a test target chip with resilient force, thereby improving reliability of chip testing.

In addition, the probe apparatus according to the present invention allows probe pins to be easily identified with the naked eye from outside.

Further, the probe apparatus according to the present invention can provide low contact resistance and excellent durability.

### DESCRIPTION OF DRAWINGS

FIG. 1 is an exploded perspective view of a probe apparatus for testing chips according to one embodiment of the present invention;

FIG. 2 is a perspective view of the probe apparatus for testing chips according to the embodiment of the present invention;

FIG. 3 is a sectional view of the probe apparatus for testing chips according to the embodiment of the present invention and test equipment; and

FIG. 4 shows various types of pinholes formed in a pin holder provided to the probe apparatus according to the embodiment of the present invention.

### LIST OF REFERENCE NUMERALS

| | |
|---|---|
| 10: Test target chip | 100: Probe apparatus |
| 110: Printed circuit board | 120: Pin holder |
| 130: Probe pin | 140: Rear cover |
| 150: Female connector | 160: Support rod |

### Best Mode

Hereinafter, embodiments of the present invention will be described.

The above and other aspects, features, and advantages of the present invention will become apparent from the detailed description of the following embodiments in conjunction with the accompanying drawings.

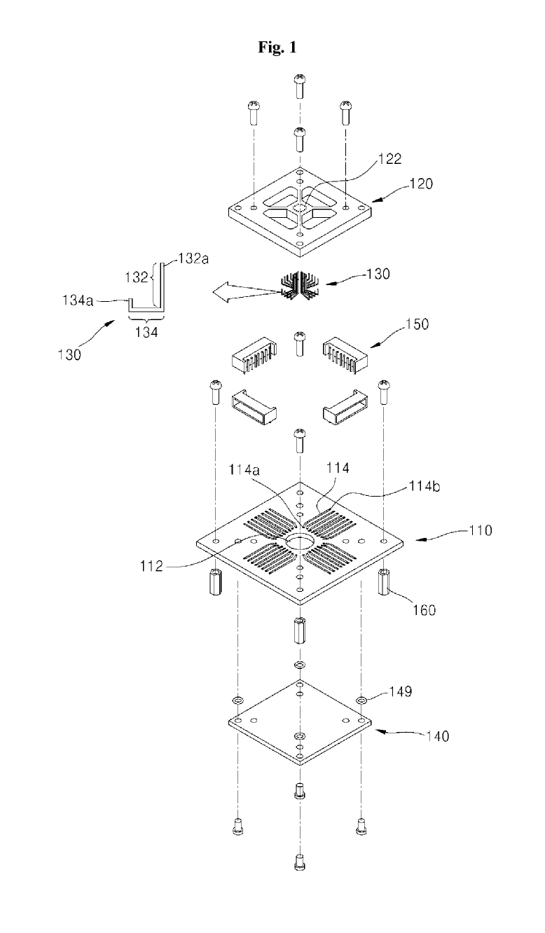

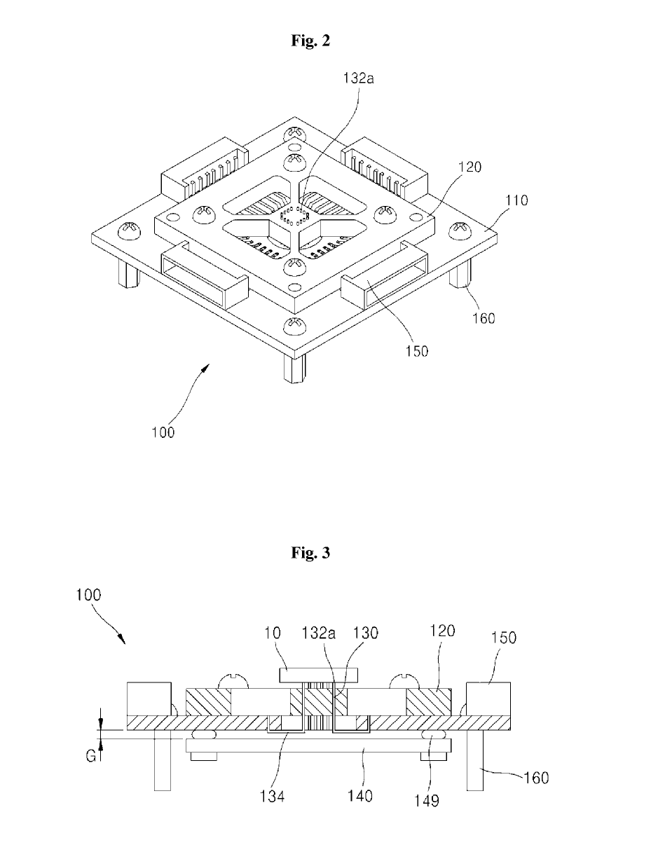

FIG. 1 is an exploded perspective view of a probe apparatus for testing chips according to one embodiment of the present invention and FIG. 2 is a perspective view of the probe apparatus for testing chips according to the embodiment of the present invention.

Referring to FIG. 1, a probe apparatus 100 for testing chips according to one embodiment of the invention includes a printed circuit board 110 having a through-hole 112 formed at a center thereof, a pin holder 120 attached to a front surface of the printed circuit board 110 and having a plurality of pinholes 122 formed therethrough, a plurality of probe pins 130 having an L-shape, a horizontal end 134a of which is connected to one end of a circuit pattern 114 formed on the printed circuit board 110 and a vertical end 132a of which is exposed through a top surface of the pin holder 120, and a rear cover 140 attached to a rear surface of the printed circuit board 110.

The probe apparatus 100 according to the embodiment enables convenient connection of an electrical contact of a small chip to test equipment.

To this end, the probe apparatus 100 according to the embodiment includes the pin holder 120, which is formed with the vertical through-holes corresponding to locations of the electrical contacts of the chip.

The L-shaped probe pins 130 are mounted on the pin holder 120, and the vertical end 132a of each of the probe pins 130 is connected to a corresponding electrical contact of the chip. The horizontal end 134a of each of the probe pins 130 is connected to a corresponding circuit pattern 114 of the printed circuit board 110. Here, the circuit pattern 114 is connected to corresponding female connectors 150.

The circuit pattern 114 formed on the printed circuit board 110 extends from a periphery of the through-hole 112 to an edge of the printed circuit board 110, the one end 114a of the circuit pattern 114 formed at the periphery of the through-hole 112 is connected to the corresponding probe pin 130, and the other end 114b of the circuit pattern 114 formed at the edge of the printed circuit board 110 is connected to the corresponding female connector 150.

The female connectors 150 are fitted to male connectors (not shown) connected to the test equipment such that the chip mounted on the probe apparatus 100 for testing chips according to the embodiment is connected to the test equipment.

The pin holder 120 may be made of a transparent material. When the pin holder 120 is made of the transparent material, deformation of the probe pins 130 can be easily identified with the naked eye without separating the pin holder 120.

The pin holder 120 may be made of crystal glass.

Crystal glass has high transparency, thereby allowing the probe pins 130 to be easily identified therethrough. Further, the crystal glass does not produce static electricity, thereby preventing foreign matter from being attached to the pinholes 122.

In the probe apparatus 100 according to the present invention, the probe pins 130 have an L-shape, which has a vertical portion 132 and a horizontal portion 134 integrally formed with each other, and the vertical end 132a of each probe pin 130 is connected to the electrical contact of the chip, thereby securing stable connection between the probe pins and the chip.

It is desirable that the probe pins 130 have resilience for stable connection. Resilience of the probe pins may be secured by resilience of a material for the probe pins and characteristics of the L-shape.

Further, the vertical portion 132 of the probe pin 130 is received in the corresponding pinhole 122 of the pin holder 120, thereby preventing deformation of the vertical end 132. Thus, the probe pins are not deformed despite repeated use and exhibit uniform connection performance.

The printed circuit board 110 includes the through-hole 112 formed at the center thereof, and the circuit pattern 114 extending from the periphery of the through-hole 112 to an outer side. The vertical portion 132 of the probe pin 130 passes through the through-hole 112.

The one end of the circuit pattern 114 disposed at the periphery of the through-hole 112 is connected to the horizontal end of the probe pin 130, and the opposite end of the circuit pattern 114 disposed outside the printed circuit board is connected to the corresponding female connector 150.

The rear cover 140 supports the horizontal portion 134 of each of the probe pins 130.

The rear cover 140 supports a lower side of the horizontal portion 134 to prevent deflection of the horizontal portion 134 and damage to a connecting portion between the horizontal end 134a and the printed circuit board 110.

The rear cover 140 may be formed of a transparent material such that the shapes of the probe pins 130 may be easily identified from outside. Further, the rear cover 140 may be formed of a material having antistatic properties. When static electricity is generated in the rear cover 140, foreign matter can be attached between the rear cover 140 and the printed circuit board.

Further, the rear cover 140 may be coupled to the printed circuit board 110 through a detachable fastener. This structure allows removal of the rear cover 140 and replacement or checking of the probe pins 130 when some of the probe pins 130 are damaged or need to be checked.

Each of the probe pins 130 has an L shape with the vertical portion 132 and the horizontal portion 134, in which the vertical end 132a of the vertical portion 132 is connected to the corresponding electrical contact of the chip, and the end 134a of the horizontal portion 134 is connected to the corresponding circuit pattern 114 of the printed circuit board 110. More particularly, when the end 134a of the horizontal portion 134 is bent in the same direction as the vertical portion 132 and is inserted into the printed circuit board 110, the probe pins 130 may be more easily connected to the printed circuit board 110.

The probe pins 130 may be formed of beryllium copper (BeCu). The probe pins formed of beryllium copper provide excellent resilient force, and are excellent in durability, as compared with phosphor bronze (P Cu) used for general spring materials.

The probe pins 130 may be plated for reduction in contact resistance.

Plating of the probe pins 130 may be performed by cleaning a base material of beryllium copper with an acid, plating the base material with copper (Cu), and then sequentially plating with nickel (Ni) and gold (Au).

An outer surface of the base material of beryllium copper may be plated with gold (Au) for reduction in contact resistance. In this case, when the base material of beryllium copper is directly plated with gold (Au), it is difficult to secure sufficient durability due to weak adhesion. Thus, a copper plated layer and a nickel plated layer are formed as intermediate layers, thereby making it possible to secure durability of the plated layers.

Since the gold (Au) plated layer is damaged and abraded by repeated use, the gold plated layer may be formed to a thickness ranging from 2 μm to 4 μm so as to be used a million times or more. A thickness of the plated layer smaller than 2 μm makes it difficult to secure sufficient use times, and a thickness of the plated layer greater than 4 μm is undesirable due to excessive increase in manufacturing costs.

Further, a plurality support rods 160 is coupled to the rear surface of the printed circuit board 110. The support rods 160 are used when the probe apparatus for testing chips according to the present invention is secured to other equipment.

FIG. 3 is a sectional view of the probe apparatus for testing chips according to the embodiment of the present invention.

As shown, when a test target chip is brought into close contact with the vertical ends of the probe pins 130 while being secured to a handler, electrical contacts of the chip are connected to the probe pins and thus are connected to test equipment (not shown) via the circuit pattern 114 of the printed circuit board 110 and the female connectors 150, thereby allowing the test equipment to test the chip 10.

When the test target chip 10 is brought into close contact with the upper ends of the probe pins 130, the probe pins are deflected downwards and resiliently deformed. In this case, the horizontal portion 134 of the probe pins 130 is restricted by the rear cover 140, and thus, the probe pins 130 are deformed only within a predetermined range.

To guide resilient deformation of the probe pins 130, a gap G may be formed between the rear cover 140 and the rear surface of the printed circuit board 110. To this end, spacers 149 may be disposed between the rear cover 140 and the printed circuit board 110 when the rear cover 140 is fastened to the printed circuit board 110. When the spacers 149 are disposed therebetween, the gap G corresponding to the thickness of the spacers is generated between the rear cover 140 and the printed circuit board 110, and the horizontal portion 134 of the probe pin 130 may move upwards and downwards within this area.

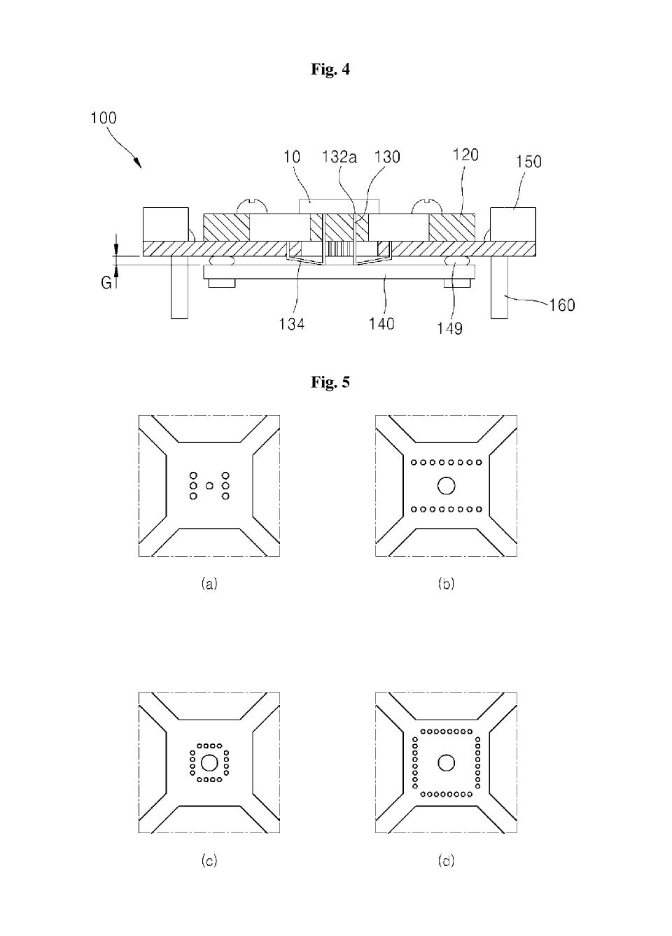

FIG. 4 shows various types of pinholes formed in the pin holder provided to the probe apparatus for testing chips according to the embodiment of the invention.

As shown, pinholes may be formed in various shapes according to a type of electrical contact of a test target chip.

FIG. 4 (a) shows arrangement of pinholes corresponding to a chip having a total of seven electrical contacts including three electrical contacts on left and right sides of the chip and one electrical contact at a center of the chip.

FIG. 4 (b) shows arrangement of pinholes corresponding to a chip having a total of sixteen electrical contacts including eight electrical contacts on upper and lower sides of the chip.

FIG. 4 (c) shows arrangement of pinholes corresponding to a chip having a total of sixteen electrical contacts including four electrical contacts on left, right, upper, and lower sides of the chip.

FIG. 4(d) shows arrangement of pinholes corresponding to a chip having a total of thirty two electrical contacts including eight electrical contacts on left, right, upper, and lower sides of the chip.

In addition, pinholes may be formed corresponding to a location of electrical contacts of various types of chips, and may be used for testing of the chips.

### INDUSTRIAL APPLICABILITY

The present invention provides a probe apparatus for testing chips in which electrical contacts of a chip can be stably connected to vertical ends of probe pins. Although the probe pins are moved upwards and downwards in the course of testing the chip, movement of the probe pins is restricted by a pin holder and a rear cover, thereby allowing the probe pins to move upwards and downwards only in a resiliently deformable area. Accordingly, the probe pins are not deformed despite increase in the number of use times.

Further, in the probe apparatus for testing chips of the present invention, beryllium copper (BeCu) having excellent durability is used as a material for the probe pins, and an outer surface of each probe pin is plated with gold, thereby securing durability and low contact resistance.

1. A probe apparatus for testing chips, comprising:
a printed circuit board having a through-hole formed at a center thereof;
a pin holder attached to a front surface of the printed circuit board and having a plurality of pinholes formed therethrough;
a plurality of probe pins each having an L shape with a vertical end and a horizontal end, the horizontal end of the probe pin being connected to one end of a circuit pattern formed on the printed circuit board, the vertical end of the probe pin being exposed through a top surface of the pinhole; and
a rear cover attached to a rear surface of the printed circuit board.

2. The probe apparatus according to claim 1, wherein the pin holder and the rear cover are formed of a transparent material.

3. The probe apparatus according to claim 2, wherein the pin holder is formed of crystal glass.

4. The probe apparatus according to claim 2, wherein the pin holder is formed of a transparent synthetic resin having antistatic properties.

5. The probe apparatus according to claim 1, wherein the pin holder and the rear cover are detachable.

6. The probe apparatus according to claim 1, wherein the probe pins are formed of beryllium copper (BeCu).

7. The probe apparatus according to claim 6, wherein each of the probe pins comprises a copper plated layer, a nickel plated layer, and a gold plated layer sequentially formed on a surface thereof.

8. The probe apparatus according to claim 7, wherein the gold plated layer has a thickness ranging from 2 μm to 4 μm.

9. The probe apparatus according to claim 1, wherein the horizontal end of the probe pin is bent in the same direction as the vertical end thereof.

10. The probe apparatus according to claim 1, further comprising:
a plurality of support rods coupled to the rear surface of the printed circuit board.

11. The probe apparatus according to claim 1, wherein a gap is formed between the printed circuit board and the rear cover.

12. The probe apparatus according to claim 11, wherein a spacer is disposed between the printed circuit board and the rear cover.

13. The probe apparatus according to claim 1, further comprising:
a female connector connected to the other end of the circuit pattern of the printed circuit board.

14. The probe apparatus according to claim 1, wherein the female connector is arranged at an edge of the printed circuit board.

15. The probe apparatus according to claim 1, wherein the circuit pattern of the printed circuit board extends from a periphery of the through-hole to an edge of the printed circuit board.
